(19) United States
(12) Patent Application Publication
(10) Pub. No.: US 2026/0180285 A1
(43) Pub. Date: Jun. 25, 2026

(54) SAMPLED GRATING DISTRIBUTED BRAGG REFLECTOR LASER DIODE WITH DISTRIBUTED MICROHEATERS

(71) Applicant: ELECTRONICS AND TELECOMMUNICATIONS RESEARCH INSTITUTE, Daejeon (KR)

(72) Inventors: Oh Kee KWON, Daejeon (KR); Chul-Wook LEE, Daejeon (KR)

(21) Appl. No.: 19/394,288

(22) Filed: Nov. 19, 2025

(30) Foreign Application Priority Data
Dec. 23, 2024 (KR) 10-2024-0193505

(51) Int. Cl. H01S 5/12; H01S 5/024; H01S 5/042; H01S 5/125

(52) U.S. Cl. CPC H01S 5/1209; H01S 5/02453; H01S 5/04256; H01S 5/125

(57) ABSTRACT

Disclosed is a sampled grating distributed Bragg reflector laser diode. The diode includes a lower clad layer including a gain region, and a first reflection region at one side of the gain region, a waveguide layer provided on the lower clad layer and including gratings in the first reflection region, an upper clad layer provided on the waveguide layer and including heating regions on the gratings and non-heating regions between the heating regions, and an upper electrode layer on the upper clad layer. The upper clad layer may include a first upper electrode on the upper clad layer in the gain region, and a first wavelength-tunable electrode including a first heater electrode on the upper clad layer in the first reflection region and first plate electrodes on the first heater electrode in the non-heating regions.

### CROSS-REFERENCE TO RELATED APPLICATION

This U.S. non-provisional patent application claims priority under 35 U.S.C. § 119 of Korean Patent Application No. 10-2024-0193505, filed on Dec. 23, 2024, the entire contents of which are hereby incorporated by reference.

### BACKGROUND

The present disclosure herein relates to a wavelength-tunable light source, and more particularly, to a sampled grating distributed Bragg reflector laser diode with distributed microheaters.

When a wavelength-tunable laser source capable of tuning an operation wavelength in a wavelength division multiplexing system is introduced, a wavelength may be dynamically assigned in a transmission stage to extend the system and increase flexibility. In the meantime, wavelength-tunable laser sources of various configurations have been reported and a distributed Bragg laser reflector diode (DBR-LD) in a monolithic integrated chip type is gaining spotlight as the most useful wavelength-tunable light source in terms of size, weight, power consumption, and cost.

### SUMMARY

The present disclosure provides a sampled grating distributed Bragg reflector laser diode capable of reducing or minimizing the power consumption while wavelength tuning is performed due to a thermal effect.

Disclosed is a sampled grating distributed Bragg reflector laser diode. An embodiment of the inventive concept provides a sampled grating distributed Bragg reflector laser diode including: a lower clad layer having a gain region, and a first reflection region at one side of the gain region; a waveguide layer provided on the lower clad layer and including gratings in the first reflection region; an upper clad layer provided on the waveguide layer and having heating regions on the gratings and non-heating regions between the heating regions; and an upper electrode layer on the upper clad layer. Here, the upper electrode layer may include: a first upper electrode provided on the upper clad layer in the gain region; and a first wavelength-tunable electrode having a first heater electrode provided on the upper clad layer in the first reflection region and first plate electrodes provided on the first heater electrode in the non-heating regions.

In an embodiment, the first plate electrodes may be wider than the first heater electrode.

In an embodiment, the lower clad layer may further have a second reflection region provided at another side of the gain region and facing the first reflection region, and the upper electrode layer may further have a second wavelength-tunable electrode on the upper clad layer in the second reflection region.

In an embodiment, the gratings may be provided in the upper clad layer in the second reflection region to define the heating regions between the non-heating regions, and the second wavelength-tunable electrode may include: a second heater electrode; and second plate electrodes provided on the second heater electrode in the non-heating regions, the second plate electrodes wider than the second heater electrode.

In an embodiment, the first upper electrode may include: a first ohmic electrode; and a first conducting electrode provided on the first ohmic electrode.

In an embodiment, the lower clad layer may further have a phase region between the gain region and the first reflection region.

In an embodiment, the upper electrode layer may further include a second upper electrode provided on the upper clad layer in the phase region and between the first upper electrode and the wavelength-tunable electrode.

In an embodiment, the second upper electrode may include: a second ohmic electrode; and a second conducting electrode provided on the second ohmic electrode.

In an embodiment, the sampled grating distributed Bragg reflector laser diode may further include an upper insulating layer between the first wavelength-tunable electrode and the upper clad layer.

In an embodiment, the first wavelength-tunable electrode may further have an intermediate electrode between the heater electrode and the plate electrodes.

In an embodiment of the inventive concept, a sampled grating distributed Bragg reflector laser diode includes: a lower clad layer having a gain region, a first reflection region at one side of the gain region, and a second gain region at another side of the gain region; a waveguide layer provided on the lower clad layer, extending from the first reflection region to the second reflection region, and including a plurality of gratings provided in each of the first reflection region and the second reflection region; an upper clad layer provided on the waveguide layer, the upper clad layer having heating regions on the gratings and non-heating regions between the heating regions; and an upper electrode layer on the upper clad layer. Here, the upper electrode layer may include: a first upper electrode provided on the upper clad layer in the gain region; and a first wavelength-tunable electrode and a second wavelength-tunable electrode provided on the upper clad layer at both sides of the first upper electrode respectively. Each of the first wavelength-tunable electrode and the second wavelength-tunable electrode may include: a first heater electrode and a second heater electrode provided on the heating regions and the non-heating regions; and first plate electrodes and second plate electrodes provided on the first heater electrode and the second heater electrode in the non-heating regions.

In an embodiment, the first plate electrodes may be wider than the first heater electrode, and the second plate electrodes may be wider than the second heater electrode.

In an embodiment, the sampled grating distributed Bragg reflector laser diode may further include an upper insulating layer between the first heater electrode and the second upper clad layer, and between the second heater electrode and the upper clad layer.

In an embodiment, the first upper electrode may include: a first ohmic electrode; and a first conducting electrode on the first ohmic electrode.

In an embodiment, the lower clad layer may further have a phase region between the gain region and the first reflection region.

In an embodiment, the upper electrode layer may further include a second upper electrode provided on the upper clad layer in the phase region and provided between the first upper electrode and the wavelength-tunable electrode.

In an embodiment, the second upper electrode may include: a second ohmic electrode; and a second conducting electrode on the second ohmic electrode.

In an embodiment, the first wavelength-tunable electrode and the second wavelength-tunable electrode may be respectively provided between the first heater electrode, and the first plate electrodes and between the second heater electrode and the second plate electrodes, the first wavelength-tunable electrode and the second wavelength-tunable further including an intermediate electrode having a same material as the first ohmic electrode and the second ohmic electrode.

In an embodiment, the first heater electrode and the second heater electrode may include a nickel-chromium alloy.

In an embodiment, the first plate electrode and the second plate electrode may include copper.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view showing an example of a sampled grating distributed Bragg reflector laser diode according to an embodiment of the inventive concept;

FIG. 2 is a cross-sectional view cut along line I-I′ of FIG. 1;

FIG. 3 is a plan view showing an example of a first wavelength-tunable electrode of FIGS. 1 and 2;

FIGS. 4 and 5 are respective cross-sectional views cut along line II-II′ and III-III′ of FIG. 3;

FIG. 6 is a plan view showing an example of a second wavelength-tunable electrode of FIGS. 1 and 2;

FIG. 7 shows graphs of examples of first and second spectra of a laser beam reflected from a rear facet reflection region and a front facet reflection region of FIG. 2;

FIG. 8 shows graphs of examples of a peak wavelength and an adjacent channel loss margin of the laser beam according to a difference in refractive index of a waveguide layer of FIG. 2;

FIG. 9 is a plan view showing an example of second heater electrodes of FIG. 1; and

FIG. 10 is a cross-sectional view showing an example of the second wavelength-tunable electrode of FIG. 6.

### DETAILED DESCRIPTION

In order to sufficiently understand the configuration and effects of the technical idea of the present invention, preferred embodiments of the technical idea of the present invention will be described with reference to the accompanying drawings. However, the technical idea of the present invention is not limited to the embodiments disclosed below, and may be implemented in various forms and various changes may be made. However, it is provided to complete the disclosure of the technical idea of the present invention through the description of the present embodiments, and to completely inform those skilled in the art of the scope of the invention to which the present invention belongs.

Like reference numerals refer to like elements throughout. Embodiments described herein will be described with reference to block diagrams, perspective views, and/or cross-sectional views, which are ideal illustrations of the technical idea of the present invention. In the drawings, the thicknesses of layers and regions are exaggerated for clarity. Accordingly, the regions illustrated in the drawings have schematic properties, and the shapes of the regions illustrated in the drawings are intended to illustrate a specific shape of a region of a device and are not intended to limit the scope of the invention. Although various terms are used to describe various elements in various embodiments of the present specification, these elements should not be limited by these terms. These terms are only used to distinguish one component from another. Embodiments described and illustrated herein also include complementary embodiments thereof.

The terms and words used in the following description and claims are to describe embodiments but are not limited the inventive concept. As used herein, the singular forms “a”, “an” and “the” are intended to include the plural forms as well, unless the context clearly indicates otherwise. It will be further understood that the terms “comprises” and/or “comprising” used herein specify the presence of stated features or components, but do not preclude the presence or addition of one or more other features or components.

Hereinafter, preferred embodiments of the inventive concept will now be described in detail with reference to the accompanying drawings.

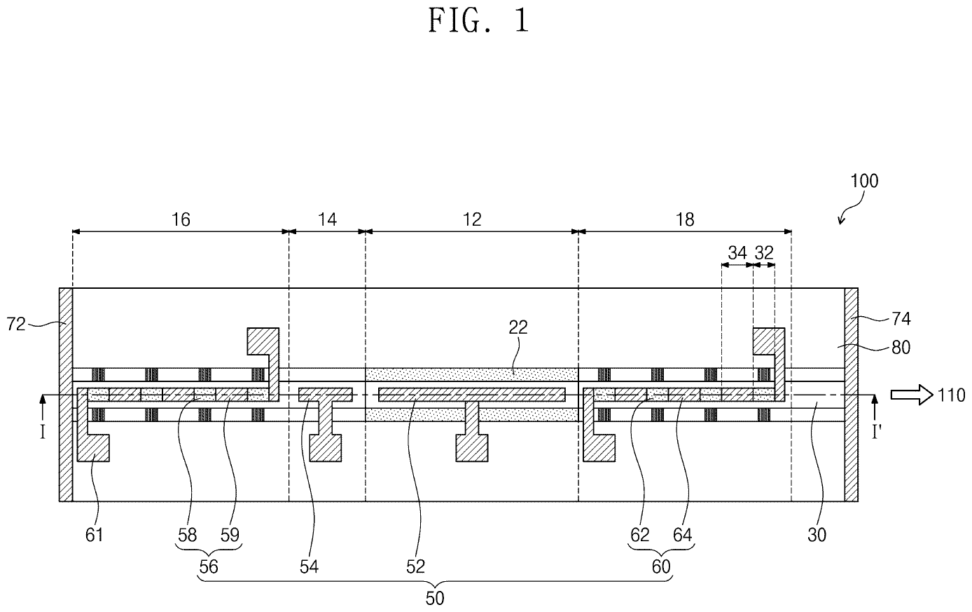

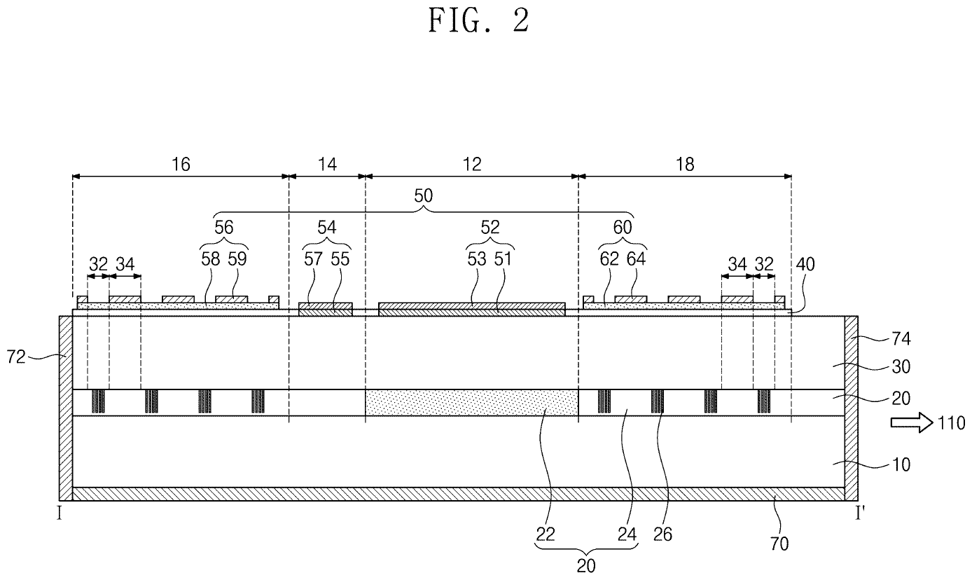

FIG. 1 shows an example of a sampled grating distributed Bragg reflector laser diode according to an embodiment of the inventive concept. FIG. 2 is a view cut along line I-I′ of FIG. 1.

Referring to FIGS. 1 and 2, the sampled grating distributed Bragg reflector laser diode (SG-DBR LD) 100 of the inventive concept may be a sampled grating distributed Bragg reflector laser diode with distributed microheaters. According to an example, the sampled grating distributed Bragg reflector laser diode 100 of the inventive concept may include a lower clad layer 10, a waveguide layer 20, an upper clad layer 30, an upper insulation layer insulating layer 40, an upper electrode layer 50, a lower electrode layer 70, a first anti-reflection layer 72, and a second anti-reflection layer 74.

The lower clad layer 10 may include an n-type InP substrate. According to an example, the lower clad layer 10 may have a gain region 12, a phase region 14, a rear facet reflection region 16, and a front facet reflection region 18.

The gain region 12 may be may be provided between the phase region 14 and the front facet reflection region 18. Although not illustrated, the gain region 12 may be provided between the rear facet reflection region 16 and the front facet reflection region 18, and the embodiment of the inventive concept is not limited thereto. The gain region 12 may a region from which the gain of a laser beam 110 is acquired.

The phase region 14 may be provided between the rear facet reflection region 16 and the gain region 12. Although not illustrated, the phase area 14 may be may be provided between the front facet reflection region 18 and the gain region 12. The phase region 14 may a region in which the phase of the laser beam 110 is controlled.

The rear facet reflection region 16 may be provided between the phase region 14 and the first anti-reflection layer 72. The rear facet reflection region 16 may be a region in which the laser beam 110 is reflected to the gain region 12 and the wavelength of the laser beam 110 is tuned.

The front facet reflection region 18 may be provided between the gain region 12 and the second anti-reflection layer 74. The front facet reflection region 18 may be a region in which the laser beam 110 is reflected to the gain region 12 and the wavelength of the laser beam 110 is tuned.

The waveguide layer 20 may be provided on the lower clad layer 10. The waveguide layer 20 may acquire the gain of the laser beam 110 and transmit the laser beam 110. The waveguide layer 20 may have a higher refractive index than the lower clad layer 10. According to an example, the waveguide layer 19 may include an active waveguide 22 and passive waveguides 24.

The active waveguide 22 may be provided on the lower clad layer 10 in the gain region 12. The active waveguide 22 may acquire the gain of the laser beam 110. For example, the active waveguide 22 may include InGaAsP. In addition, the active waveguide 22 may include a multi-quantum well layer.

The passive waveguides 24 may be provided on the lower clad layer 10 in the phase region 14, the rear facet reflection region 16, and the front facet reflection region 18. The passive waveguides 24 may transmit the laser beam 110. For example, the passive waveguides 24 may include intrinsic InP. Alternatively, the passive waveguides 24 may include InGaAs, and the embodiment of the inventive concept is not limited thereto. According to an example, the passive waveguide 24 in each of the rear facet reflection region 16 and the front facet reflection region 18 may include a plurality of gratings 26. The gratings 26 may reflect a portion of the laser beam 110 and transmit another portion. Each of the gratings 26 may be a sampled grating. For example, the grating may include InGaAsP. Alternatively, the gratings 26 may include a defect or vacancy, but the embodiment of the inventive concept is not limited thereto.

The upper clad layer 30 may be provided on the waveguide layer 20. The upper clad layer 30 may have a lower refractive index than the waveguide layer 20. The upper clad layer 30 may include n-type InP. According to an example, the upper clad layer 30 may include heating regions 32 and non-heating regions 34. The heating regions 32 and the non-heating regions 34 may be provided in the rear facet reflection region 16 and the front facet reflection region 18.

The heating regions 32 may be provided on the gratings 26. The heating regions 32 may be overlapping regions aligned to the gratings 26. The heating regions 32 may be regions in which the gratings 26 are heated.

The non-heating regions 34 may be provided between the heating regions 32. The non-heated regions 34 may be offset regions or non-overlapping regions between the gratings 26. The non-heating regions 34 may be conducting regions in which a current flows or is transferred without heating the gratings 26.

The upper insulating layer 40 may be provided on the upper clad layer 30. The upper insulating layer 40 may expose portions of the upper clad layer 30 in the gain region and the phase region 14. The upper insulating layer 40 may be provided on the upper cladding layer 30 in the rear facet reflection region 16 and the front facet reflection region 18. For example, the upper insulating layer 40 may include a dielectric of silicon oxide or silicon nitride.

The upper electrode layer 50 may be provided on the upper insulating layer 40 and the upper clad layer 30. According to an example, the upper electrode layer 50 may include a first upper electrode 52, a phase control electrode 54, a first wavelength-tunable electrode 56, and a second wavelength-tunable electrode 60.

The first upper electrode 52 may be provided on the upper clad layer 30 in the gain region 12. The first upper electrode 52 may use a gain current provided to the lower electrode layer 70 to control the power of the laser beam 110. According to an example, the first upper electrode 52 may include a first ohmic electrode 51 and a first conducting electrode 53. The first ohmic electrode 51 may be provided on the upper clad layer 30 in the gain region 12. Although not illustrated, p-type InGaAs may be provided between the first ohmic electrode 51 and the upper clad layer. The first ohmic electrode 51 may derive or provide ohmic contact between the upper clad layer 30 and the first conducting electrode 53. The first ohmic electrode 51 may include aluminum (Al), Nickel (Ni), or tungsten (W). The first conducting electrode 53 may be provided on the first ohmic electrode 51. The first conducting electrode 53 may be connected to a pad 61. Although not illustrated, a gain voltage and/or a gain current may be provided between the pad 61 of the first conducting electrode 53 and the lower electrode layer 70. The first conducting electrode 53 may include gold (Au) provided through a metal plating process.

The phase control electrode 54 may be provided on the upper clad layer 30 in the phase region 14. The phase control electrode 54 may use a phase control current provided to the lower electrode layer 70 to control the phase of the wavelength of the laser beam 110. According to an example, the phase control electrode 54 may include a second ohmic electrode 55 and a second conducting electrode 57. The second ohmic electrode 55 may be provided on the upper clad layer 30 in the phase area 14. Although not illustrated, an ohmic layer (p-type InGaAs) may be provided between the second ohmic electrode 55 and the upper clad layer 30. The second ohmic electrode 55 may derive or provide ohmic contact between the upper clad layer 30 and the second conducting electrode 57.

The second ohmic electrode 55 may have the same material as the first ohmic electrode 51. The second ohmic electrode 55 may include aluminum (Al), Nickel (Ni), or tungsten (W). The second conducting electrode 57 may be provided on the second ohmic electrode 55. The second conducting electrode 57 may have the same material as the first contacting electrode 53. The second conducting electrode 57 may include gold (Au). Although not illustrated, a phase control voltage and/or a phase control current may be provided between the pad 61 of the second conducting electrode 57 and the lower electrode layer 70.

The first wavelength-tunable electrode 56 may be provided on the upper insulating layer 40 in the rear facet reflection region 16. The first wavelength-tunable electrodes 56 may heat the upper clad layer 30 and the passive waveguide 24 to tune the wavelength of the laser beam 110.

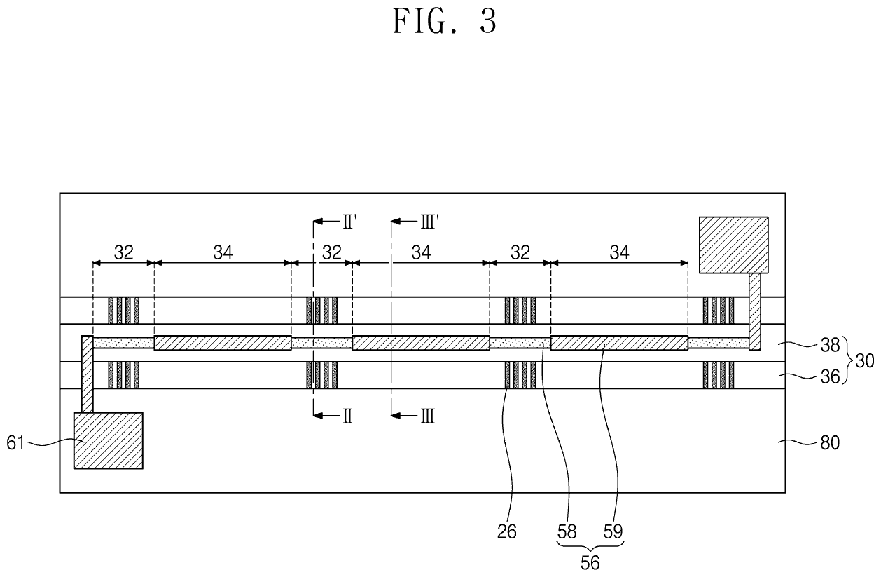

FIG. 3 shows an example of the first wavelength-tunable electrode 56 of FIGS. 1 and 2.

Referring to FIGS. 1 to 3, the first wavelength-tunable electrode 56 may include a first heater electrode 58 and first plate electrodes 59.

The first heater electrode 58 may be provided on the upper insulating layer 40 in the heating regions 32 and the non-heating regions 34. The first heater electrode 58 may extend from one side to the other side of the rear facet reflection region 16 along the passive waveguides 24 in one direction. The first heater electrode 58 may heat the gratings 26 and the upper clad layer 30 on the gratings 26 to tune the wavelength of the laser beam 110. The first heater electrode 58 may be a microheater electrode. For example, the first heater electrode 58 may include titanium (Ti), platinum (Pt), gold (Au) or chromium (Cr), and a nickel-chromium alloy.

The first plate electrodes 59 may be provided on the first heater electrode 58 in the non-heating regions 34 between the gratings 26. According to an example, each of the first plate electrodes 59 may be wider than the first heater electrode 58 in a direction crossing the extension direction of the waveguide layer 20. The first plate electrodes 59 may selectively expose the first heater electrode 58 of the heating regions 32. The first plate electrodes 59 may connect the first heater electrode 58 to the pads 61. The first plate electrodes 59 may reduce the resistance of the first heater electrode 58 in the non-heating regions 34. The first plate electrodes 59 may connect in series portions exposed in the heating regions 32 of the first heater electrode 58. The first plate electrodes 59 may reduce heat generation of, and reduce or minimize power consumption of the first heater electrode 58 in the non-heating regions 34. The first heater electrode 58 may selectively heat the gratings 26 in the heating regions 32 and the upper clad layer 30 on the gratings 26 to tune the wavelength of the laser beam 110. For example, the first plate electrodes 59 may include copper (Cu) provided with a plating method. Alternatively, the first plate electrodes 59 may include gold (Au).

Accordingly, the sampled grating distributed Bragg reflector laser diode 100 may use the first wavelength-tunable electrodes 56 including the first heater electrode 58 and the first plate electrodes 59, which are provided on the first heater electrode 58 and partially expose the first heater electrode 58 between the gratings 26, to reduce or minimize the power consumption.

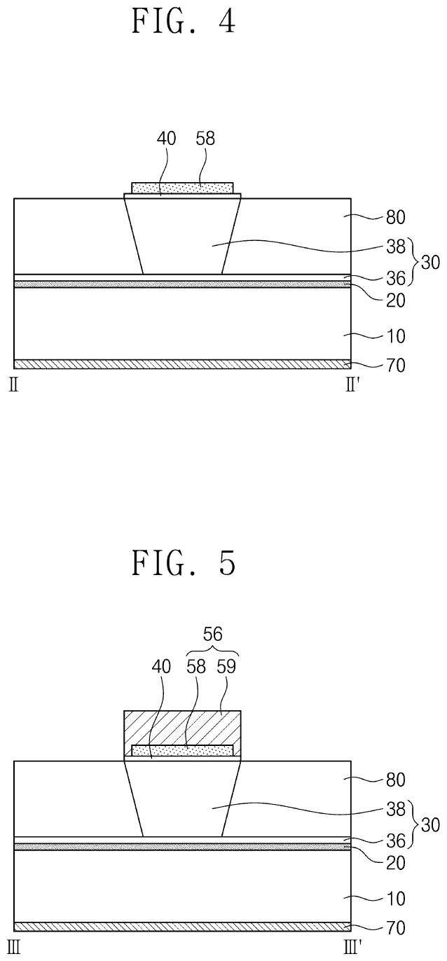

FIGS. 4 and 5 respectively show views cut along lines II-II′ and III-III′ of FIG. 3.

Referring to FIGS. 4 and 5, the upper clad layer 30 may include a first upper clad layer 36 and a second upper clad layer 38. The first upper clad layer 36 may cover the entire upper surface of the waveguide layer 20. The second upper clad layer 38 may be provided on the center of the waveguide layer 20. The second upper clad layer 38 may have a reverse-mesa structure in a cross-sectional view. A planarization insulating layer 80 may have an upper surface coplanar with an upper surface of the second upper clad layer 38. The planarization insulating layer 80 may include a polymer or a dielectric, and the embodiment of the inventive concept is not limited thereto.

Referring to FIG. 5, the first plate electrode 59 may be wider than the first heater electrode 58. The first plate electrode 59 may be provided on an upper surface and sidewall surfaces of the heater electrode 58.

Referring again to FIGS. 1 and 2, the second wavelength-tunable electrode 60 may be provided on the upper insulating layer 40 in the front facet reflection region 18. The second wavelength-tunable electrodes 60 may heat the upper clad layer 30 and the passive waveguide 24 to tune the wavelength of the laser beam 110. The first wavelength-tunable electrode 56 and the second wavelength-tunable electrode 60 may increase and maximize wavelength tuning of the laser beam 110 through the Vernier effect.

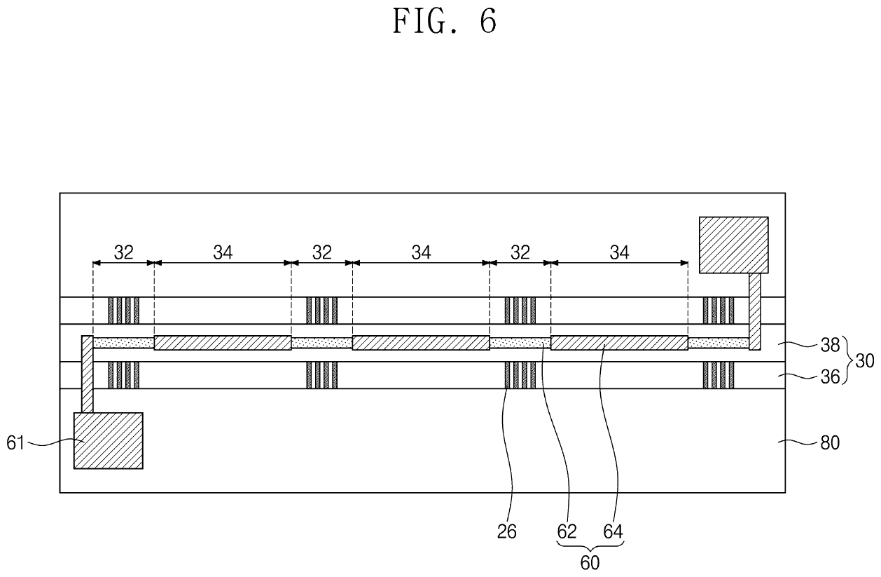

FIG. 6 shows an example of the second wavelength-tunable electrode 60 of FIGS. 1 and 2.

Referring to FIG. 6, the second wavelength-tunable electrode 60 may be configured identically to the first wavelength-tunable electrode 56 of FIGS. 3 to 5. According to an example, the second wavelength-tunable electrode 60 may include a second heater electrode 62 and a second plate electrode 64.

The second heater electrode 62 may be provided on the second upper clad layer 38 in the heating region 32. Although not illustrated, the second heater electrode 62 may extend from one side to the other side of the front facet reflection region 18 along the passive waveguides 24 in one direction. The second heater electrode 62 may heat the gratings 26 and the upper clad layer 30 on the gratings 26 to tune the wavelength of the laser beam 110. The second heater electrode 62 may be a microheater electrode. For example, the second heater electrode 62 may include a nickel-chromium alloy.

The second plate electrodes 64 may be provided on the second heater electrode 62 in the non-heating regions 34. The second plate electrodes 64 may be wider than the second heater electrode 62 in a direction crossing the extension direction of the waveguide layer 20. The second plate electrodes 64 may selectively expose the second heater electrode 62 of the heating regions 32. The second plate electrodes 64 may connect the second heater electrode 62 to the pads 61. The second plate electrodes 64 may reduce the resistance of the second heater 62 in the non-heating regions 34. The second plate electrodes 64 may connect in series portions exposed in the heating regions 32 of the first heater electrode 62. The second plate electrodes 64 may reduce heat generation of, and reduce or minimize power consumption of the second heater electrode 62 in the non-heating regions 34. The second heater electrode 62 may selectively heat the gratings 26 in the heating regions 32 and the upper clad layer 30 on the gratings 26 to tune the wavelength of the laser beam 110. For example, the second plate electrodes 64 may include gold (Au) provided with a plating method, but the embodiment of the inventive concept is not limited thereto.

Accordingly, the sampled grating distributed Bragg reflector laser diode 100 of the inventive concept may use the second wavelength-tunable electrodes 60 including the second heater electrode 62 and the second plate electrodes 64, which are provided on the second heater electrode 62 and partially expose the second heater electrode 62 between the gratings 26, to reduce or minimize the power consumption.

Referring again to FIGS. 1 and 2, the lower electrode layer 70 may be provided on a lower surface of the lower clad layer 10. The lower clad layer 10 may be grounded. For example, the lower clad layer 10 may include n-type InP.

The first anti-reflection layer 72 may be provided on sidewalls of the lower clad layer 10, the waveguide layer 20, and the upper clad layer 30 in the rear facet reflection region 16. The first anti-reflection layer 72 may be an anti-reflection layer at rear facet. For example, the first anti-reflection layer 74 may include an insulating layer including SiO₂, SiNₓ, Ta₂O₃, or Al₂O₃, and the embodiment of the inventive concept is not limited thereto.

The second anti-reflection layer 74 may be provided on sidewalls of the lower clad layer 10, the waveguide layer 20, and the upper clad layer 30 in the front facet reflection region 18. The second anti-reflection layer 74 may be an anti-reflection layer at front facet. The second anti-reflection layer 22 may reflect a portion of the laser beam 110 to the active waveguide 22, and transmit another portion of the laser beam 110. The laser beam 110 may be output outside the second anti-reflection layer 74.

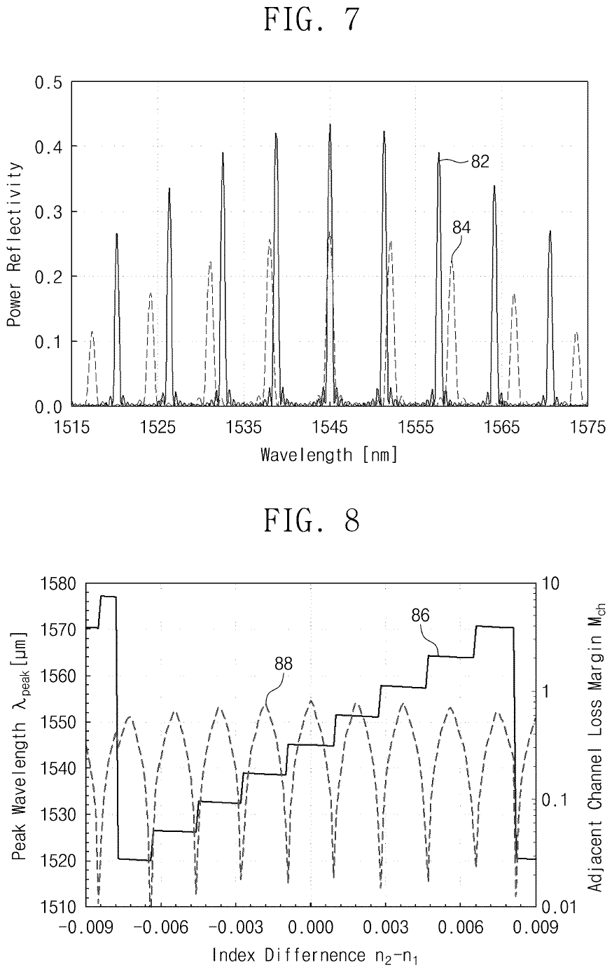

FIG. 7 shows examples of a first spectrum 82 and a second spectrum 84 of the laser beam 110 reflected from the rear facet reflection region 16 and the front facet reflection region 18, respectively.

Referring to FIGS. 2 and 7, the gratings 26 may reflect the laser beam 110 of the first spectrum 82 in the rear facet reflection region 16, and reflect the laser beam 110 of the second spectrum 84 in the front facet reflection region 18. The width of the first spectrum 82 may be smaller or narrower than that of the second spectrum 84. A first current provided to the first wavelength-tunable electrode 56 may be greater than a second current provided to the second wavelength-tunable electrode 60. The laser beam 110 may have a wavelength band of about 1545 nm in which the first spectrum 82 overlaps the second spectrum 84. The laser beam 110 in which the first spectrum 82 overlaps the second spectrum 84 may be resonated and output to the outside through the second anti-reflection layer 74. The laser beam 110 in which the first spectrum 82 does not overlap the second spectrum 84 may be reflected between the first anti-reflection layer 72 and the second anti-reflection layer 74.

FIG. 8 shows examples of a peak wavelength 86 (λₚₑₐₖ) and an adjacent channel loss margin 88 (M_{ch}) of the laser beam 110 according to a difference in refractive index of the waveguide layer 20 of FIG. 2.

Referring to FIG. 8, the peak wavelength 86 of the laser beam 110 may increase in a step type in proportion to a difference in refractive index of the waveguide layer 20, which varies according to currents provide to the first wavelength-tunable electrode 56 and the second wavelength-tunable electrode 60, and increase or decrease between 0 and 1 at each step of the peak wavelength 86. The wavelength of the laser beam 110 may be tuned between about 1530 nm and about 1570 nm with respect to the difference in refractive index of about +0.01 of the waveguide layer 20 in the rear facet reflection region 16 and the front facet reflection region 18. Namely, the wavelength of the laser beam 110 may be tuned in about 50 nm band. The adjacent channel loss margin 88 may be a generalized value calculated as a ratio of the maximum reflectivity to an adjacent reflectivity (the maximum reflectivity/an adjacent reflectivity).

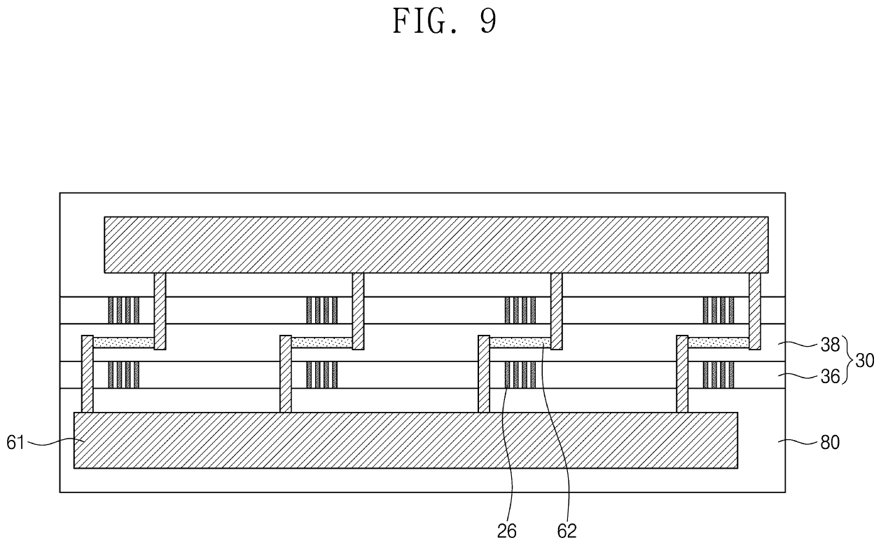

FIG. 9 shows an example of the second heater electrodes 62 of FIG. 1.

Referring to FIG. 9, the second heater electrodes 62 may be individually provided on the gratings 26. The second heater electrodes 62 may be individually connected to the pads 61 at both sides of the upper clad layer 30. The second heater electrodes 62 may be individually connected to the pads 61 through feeding lines. Although not illustrated, the first heater electrodes 58 may be individually provided on the gratings 26. The first heater electrodes 58 may be individually connected to the pads 61 through feeding lines.

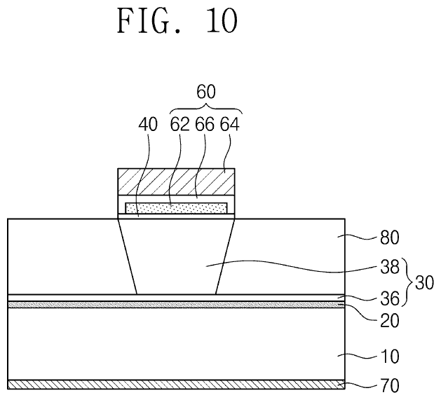

FIG. 10 shows an example of the second wavelength-tunable electrode 60 of FIG. 6.

Referring to FIG. 10, the second wavelength-tunable electrode 60 may further include a second intermediate electrode 66. The second intermediate electrode 66 may be provided between the second heater electrode 62 and the second plate electrode 64. The second intermediate electrode 66 may have resistance smaller than that of the second heater electrode 62 and greater than that of the second plate electrode 64. The resistance of the second intermediate electrode 66 may be smaller than that of the second plate electrode 64, and the embodiment of the inventive concept is not limited thereto. The second intermediate electrode 66 may include the same material as the first ohmic electrode 51 and the second ohmic electrode 55 of FIG. 2. For example, the second intermediate electrode 66 may include aluminum (Al), Nickel (Ni), or tungsten (W).

Although not illustrated, the first wavelength-tunable electrode 56 may be configured identically to the second wavelength-tunable electrode 60. According to an example, the first wavelength-tunable electrode 56 may further include a first intermediate electrode between the first heater electrode 58 and the first plate electrode 59. The first intermediate electrode 66 may have resistance smaller than that of the first heater electrode 58 and greater than that of the first plate electrode 59. The resistance of the first intermediate electrode 66 may be smaller than that of the first plate electrode, and the embodiment of the inventive concept is not limited thereto. The first intermediate electrode 66 may include the same material as the first ohmic electrode 51 and the second ohmic electrode 55. For example, the first intermediate electrode may include aluminum (Al), Nickel (Ni), or tungsten (W).

A sampled grating distributed Bragg reflector laser diode according to embodiments of the inventive concept may reduce or minimize the power consumption by means of the heater electrodes and the wavelength-tunable electrodes including the plate electrodes that are provided on the heater electrodes to partially expose the heater electrodes between the gratings.

The embodiments of the present disclosure have been described above with reference to the accompanying drawings, but those skilled in the art will understand that the present disclosure may be implemented in another concrete form without changing the technical spirit or an essential feature thereof. It is therefore to be understood that the above-described subject matter is to be considered illustrative and not restrictive.

What is claimed is:

1. A sampled grating distributed Bragg reflector laser diode comprising:
a lower clad layer having a gain region, and a first reflection region at one side of the gain region;
a waveguide layer provided on the lower clad layer and including gratings in the first reflection region;
an upper clad layer provided on the waveguide layer and having heating regions on the gratings and non-heating regions between the heating regions; and
an upper electrode layer on the upper clad layer,
wherein the upper electrode layer includes:
a first upper electrode provided on the upper clad layer in the gain region; and
a first wavelength-tunable electrode having a first heater electrode provided on the upper clad layer in the first reflection region and first plate electrodes provided on the first heater electrode in the non-heating regions.

2. The sampled grating distributed Bragg reflector laser diode of claim 1,
wherein the first plate electrodes are wider than the first heater electrode.

3. The sampled grating distributed Bragg reflector laser diode of claim 1,
wherein the lower clad layer further has a second reflection region provided at another side of the gain region facing the first reflection region, and
the upper electrode layer further has a second wavelength-tunable electrode provided on the upper clad layer in the second reflection region.

4. The sampled grating distributed Bragg reflector laser diode of claim 3,
wherein the gratings are provided in the upper clad layer in the second reflection region to define the heating regions between the non-heating regions, and
the second wavelength-tunable electrode includes:
a second heater electrode; and
second plate electrodes provided on the second heater electrode in the non-heating regions, the second plate electrodes wider than the second heater electrode.

5. The sampled grating distributed Bragg reflector laser diode of claim 1,
wherein the first upper electrode includes:
a first ohmic electrode; and
a first conducting electrode provided on the first ohmic electrode.

6. The sampled grating distributed Bragg reflector laser diode of claim 1,
wherein the lower clad layer further has a phase region between the gain region and the first reflection region.

7. The sampled grating distributed Bragg reflector laser diode of claim 6,
wherein the upper electrode layer further includes a second upper electrode provided on the upper clad layer in the phase region and provided between the first upper electrode and the wavelength-tunable electrode.

8. The sampled grating distributed Bragg reflector laser diode of claim 7,
wherein the second upper electrode comprises:
a second ohmic electrode; and
a second conducting electrode provided on the second ohmic electrode.

9. The sampled grating distributed Bragg reflector laser diode of claim 1,
further comprising an upper insulating layer between the first wavelength-tunable electrode and the upper clad layer.

10. The sampled grating distributed Bragg reflector laser diode of claim 1,
wherein the first wavelength-tunable electrode further has an intermediate electrode between the heater electrode and the plate electrodes.

11. A sampled grating distributed Bragg reflector laser diode comprising:
a lower clad layer having a gain region, a first reflection region at one side of the gain region, and a second gain region at another side of the gain region;
a waveguide layer provided on the lower clad layer, extending from the first reflection region to the second reflection region, and including a plurality of gratings provided in each of the first reflection region and the second reflection region;
an upper clad layer provided on the waveguide layer, the upper clad layer having heating regions on the gratings and non-heating regions between the heating regions; and
an upper electrode layer on the upper clad layer,
wherein the upper electrode layer includes:
a first upper electrode provided on the upper clad layer in the gain region; and
a first wavelength-tunable electrode and a second wavelength-tunable electrode provided on the upper clad layer at both sides of the first upper electrode respectively,
wherein each of the first wavelength-tunable electrode and the second wavelength-tunable electrode includes:
a first heater electrode and a second heater electrode provided on the heating regions and the non-heating regions; and
first plate electrodes and second plate electrodes provided on the first heater electrode and the second heater electrode in the non-heating regions.

12. The sampled grating distributed Bragg reflector laser diode of claim 11,
wherein the first plate electrodes are wider than the first heater electrode, and
the second plate electrodes are wider than the second heater electrode.

13. The sampled grating distributed Bragg reflector laser diode of claim 11,
further comprising an upper insulating layer between the first heater electrode and the second upper clad layer, and between the second heater electrode and the upper clad layer.

14. The sampled grating distributed Bragg reflector laser diode of claim 11,
wherein the first upper electrode comprises:
a first ohmic electrode; and
a first conducting electrode on the first ohmic electrode.

15. The sampled grating distributed Bragg reflector laser diode of claim 14,
wherein the lower clad layer further has a phase region between the gain region and the first reflection region.

16. The sampled grating distributed Bragg reflector laser diode of claim 15,
wherein the upper electrode layer further includes a second upper electrode provided on the upper clad layer in the phase region and provided between the first upper electrode and the wavelength-tunable electrode.

17. The sampled grating distributed Bragg reflector laser diode of claim 16,
wherein the second upper electrode comprises:
a second ohmic electrode; and
a second conducting electrode on the second ohmic electrode.

18. The sampled grating distributed Bragg reflector laser diode of claim 17,
wherein the first wavelength-tunable electrode and the second wavelength-tunable electrode are respectively provided between the first heater electrode and the first plate electrodes, and between the second heater electrode and the second plate electrodes, the first wavelength-tunable electrode and the second wavelength-tunable electrode further including an intermediate electrode having a same material as the first ohmic electrode and the second ohmic electrode.

19. The sampled grating distributed Bragg reflector laser diode of claim 11,
wherein the first heater electrode and the second heater electrode comprise a nickel-chromium alloy.

20. The sampled grating distributed Bragg reflector laser diode of claim 11,
wherein the first plate electrode and the second plate electrode comprise copper.
